(19) United States
(12) Patent Application Publication
(10) Pub. No.: US 2011/0121271 A1
(43) Pub. Date: May 26, 2011

(54) Organic light emitting diode display

(76) Inventors: Hee-Song Jeon, Yongin-City (KR); Soon-Ryong Park, Yongin-City (KR)

(21) Appl. No.: 12/923,067

(22) Filed: Aug. 31, 2010

(30) Foreign Application Priority Data
Nov. 25, 2009 (KR) 10-2009-0114806

(51) Int. Cl. H01L 51/50

(52) U.S. Cl. 257/40; 257/E51.018

(57) ABSTRACT

An organic light emitting diode (OLED) display is provided. The OLED display includes a substrate main body, an OLED on the substrate main body, and a capping layer on the OLED. The capping layer includes a film having at least two layers of different refractive indexes.

### BACKGROUND

1. Field

The described technology relates generally to an organic light emitting diode (OLED) display. More particularly, the described technology relates generally to an OLED display that improves light efficiency.

2. Description of the Related Art

An OLED display is a self-luminance display device that displays an image with an OLED that emits light. Unlike a liquid crystal display (LCD), the OLED display does not require a separate light source and thus can have a relatively reduced thickness and weight. Further, the OLED display provides high quality characteristics, e.g., low power consumption, high luminance, and fast reaction speed.

The OLED generally has a hole injection electrode, an organic emission layer, and an electron injection electrode. The OLED emits light by energy that is generated when excitons that are formed by coupling of holes from the hole injection electrode and electrons from the electron injection electrode within the organic emission layer drop to a ground state.

In order to increase usability of the OLED display, various methods that can improve light efficiency by effectively extracting light that is generated in the organic light emitting layer are needed.

The above information disclosed in this Background section is only for enhancement of understanding of the background of the described technology and therefore it may contain information that does not form the prior art that is already known in this country to a person of ordinary skill in the art.

### SUMMARY

Embodiments are therefore directed to an OLED display, which substantially overcomes one or more of the problems due to the limitations and disadvantages of the related art.

It is therefore a feature of an embodiment to provide an OLED display having improved light efficiency.

At least one of the above and other features and advantages may be realized by providing a substrate main body, an OLED on the substrate main body; and a capping layer that is formed on the OLED. The capping layer includes a multiple-layered film having different refractive indexes.

The capping layer may be formed by alternately stacking at least one high refractive film and at least one low refractive film. The high refractive film may be disposed at a top layer that is relatively farthest separated from the OLED.

The high refractive film may have a refractive index within a range that is greater than or equal to 1.7 and less than 2.7. The high refractive film may be made of at least one of an inorganic material and an organic material. The inorganic material may include at least one of zinc oxide, titanium oxide, zirconium oxide, silicon oxide, niobium oxide, tantalum oxide, tin oxide, nickel oxide, indium nitride, and gallium nitride. The organic material may be a polymer.

The low refractive film may have a refractive index within a range that is greater than 1.3 and less than 1.7. The low refractive film may be made of at least one of an inorganic material and an organic material. The inorganic material may include at least one of silicon oxide and magnesium fluoride. The organic material may be a polymer.

The OLED display may further include an encapsulation substrate that adheres and seals with the substrate main body to cover the OLED, wherein the encapsulation substrate and the OLED have a separation space therebetween.

The OLED display may further include a gas disposed in the separation space between the encapsulation substrate and the OLED. The gas may have a refractive index that is relatively lower than that of the high refractive film.

The OLED display may further include a non-gaseous filler disposed in the separation space between the encapsulation substrate and the OLED. The non-gaseous filler may have a refractive index that is relatively lower than that of the high refractive film. The non-gaseous filler may be an organic material, e.g., a polymer.

In the OLED display, the OLED may include a first electrode, an organic emission layer that is formed on the first electrode, and a second electrode that is formed on the organic light emitting layer and that is disposed relatively most adjacent to the capping layer. The second electrode may be made of one of a transparent material and a transflective material. The first electrode may be formed with a reflective layer.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a layout view of a pixel of an OLED display according to a first exemplary embodiment.

FIG. 2 illustrates a cross-sectional view of the pixel taken along line of FIG. 1.

FIG. 3 illustrates a cross-sectional view of an OLED display according to a second exemplary embodiment.

### DETAILED DESCRIPTION

Korean Patent Application No. 10-2009-0114806, filed on Nov. 25, 2009, in the Korean Intellectual Property Office, and entitled: “Organic Light Emitting Diode Display,” is incorporated by reference herein in its entirety.

Exemplary embodiments will be described more fully hereinafter with reference to the accompanying drawings, in which exemplary embodiments are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification. Further, like reference numerals designate like elements in several exemplary embodiments and are representatively described in the first exemplary embodiment and elements different from those of the first exemplary embodiment will be described in a second exemplary embodiment.

In the drawings, the thickness of layers, films, panels, regions, etc., may be exaggerated for clarity. In the drawings, for better understanding and ease of description, thicknesses of some layers and areas are excessively displayed. It will be understood that when an element such as a layer, film, region, or substrate is referred to as being “on” another element, it can be directly on the other element or intervening elements may also be present.

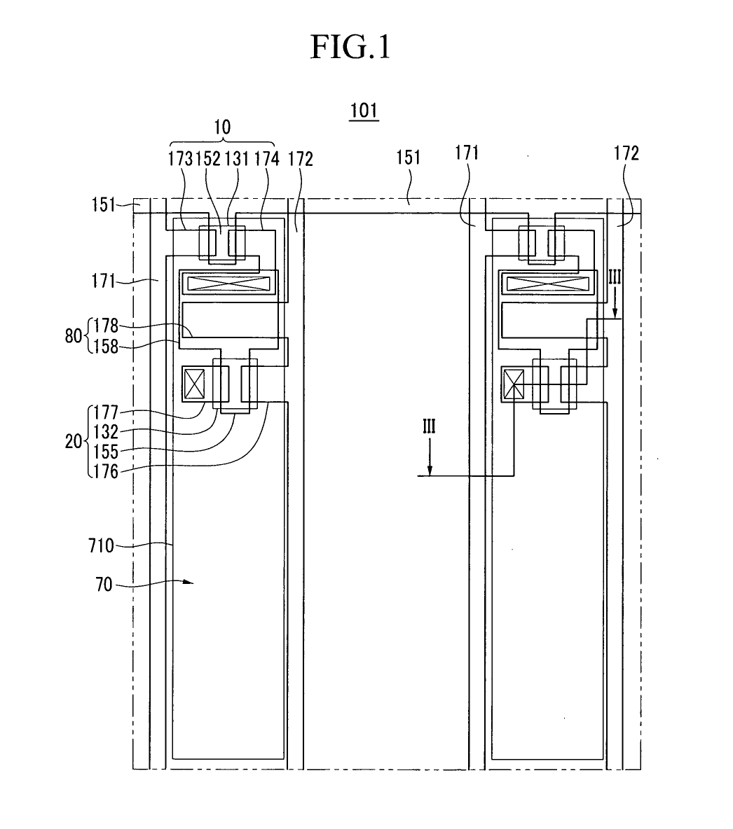

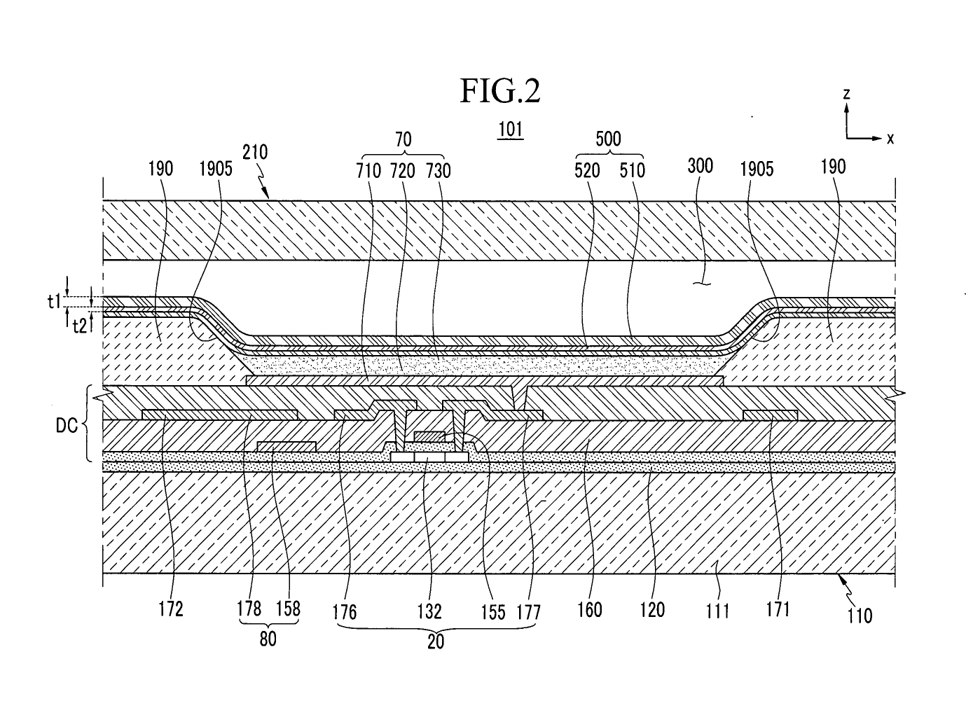

Hereinafter, a first exemplary embodiment will be described with reference to FIGS. 1 and 2.

As shown in FIGS. 1 and 2, an OLED display 101 according to the first exemplary embodiment may include a substrate main body 111, a driving circuit DC, an OLED 70, a capping layer 500, and an encapsulation substrate 210. The OLED display 101 may further include a buffer layer 120 and a pixel defining film 190.

The substrate main body 111 may be an insulation substrate, e.g., glass, quartz, ceramic, or plastic. However, the first exemplary embodiment is not limited thereto, and the substrate main body 111 may be formed with a conductive substrate, e.g., a metal substrate such as stainless steel.

The buffer layer 120 may be disposed on the substrate main body 111. Further, the buffer layer 120 may be formed with at least one of various inorganic films and organic films. The buffer layer 120 may serve to planarize a surface while preventing undesirable components, e.g., impurities or moisture, from penetrating to the driving circuit DC or the OLED 70. However, the buffer layer 120 is not always necessary and may be omitted according to kind and process conditions of the substrate main body 111.

The driving circuit DC driving the OLED 70 may be on the buffer layer 120 and may include a plurality of thin film transistors 10 and 20. That is, the OLED 70 displays an image by emitting light according to a driving signal that is received from the driving circuit DC.

The OLED 70 may include a first electrode 710, e.g., an anode that injects holes, a second electrode 730, e.g., a cathode that injects electrons, and an organic emission layer 720 between the first electrode 710 and the second electrode 730. That is, the first electrode 710, the organic emission layer 720, and the second electrode 730 may be sequentially stacked to form the OLED 70. However, the first exemplary embodiment is not limited thereto. For example, the first electrode 710 may be a cathode and the second electrode 730 may be an anode.

In the first exemplary embodiment, the first electrode 710 is formed with a reflective layer and the second electrode 730 is formed with a transflective layer. Therefore, light generated in the organic emission layer 720 is emitted by passing through the second electrode 730. That is, in the first exemplary embodiment, the OLED display 101 has a front light emitting structure.

A reflective layer and a transflective layer may be formed using at least one of magnesium (Mg), silver (Ag), gold (Au), calcium (Ca), lithium (Li), chromium (Cr), and aluminum (Al), or alloys thereof In this case, whether the layer is reflective or transflective is determined by its thickness. As the thickness of such a layer decreases, transmittance of light increases and, as the thickness of such a layer increases, transmittance of light decreases. In general, such a layer will be reflective if it is thicker than about 200 nm or less.

Further, the first electrode 710 may further include a transparent conductive layer. That is, the first electrode 710 may have a multilayer structure including a reflective layer and a transparent conductive layer. The transparent conductive layer of the first electrode 710 may be disposed between the reflective layer and the organic emission layer 720. Further, the first electrode 710 may be a three layer structure in which the transparent conductive layer, the reflective layer, and the transparent conductive layer are sequentially stacked.

The transparent conductive layer may be made of a transparent material having a relatively high work function, e.g., indium tin oxide (ITO), indium zinc oxide (IZO), zinc oxide (ZnO), or indium oxide (In₂O₃). Therefore, holes may be smoothly injected through the first electrode 710.

The second electrode 730 may be formed with a transparent conductive layer. When the second electrode 730 is formed with a transparent conductive layer, the second electrode 730 may serve as an anode that injects holes. In this case, the first electrode 710 may serve as a cathode formed with only a reflective layer.

Further, the organic emission layer 720 may be a multilayer structure including at least one of an emission layer, a hole injection layer (HIL), a hole-transporting layer (HTL), an electron-transporting layer (ETL), and an electron-injection layer (EIL). Other than the emission layer, the remaining layers may be omitted as needed. When the organic emission layer 720 includes all the above-described layers, the HIL is disposed on the first electrode 710, which is an anode, and the HTL, the emission layer, the ETL, and the EIL are sequentially stacked on the HIL. Further, the organic emission layer 720 may further include other layers, as needed.

The pixel defining film 190 has an opening 1905. The opening 1905 of the pixel defining film 190 exposes a portion of the first electrode 710. The first electrode 710, the organic emission layer 720, and the second electrode 730 are sequentially stacked within the opening 1905 of the pixel defining film 190. Here, the second electrode 730 is formed on the pixel defining film 190 as well as the organic emission layer 720. Layers of the organic emission layer 720, except for the emission layer, may be disposed between the pixel defining film 190 and the second electrode 730. The OLED 70 emits light in the organic emission layer 720 within the opening 1905 of the pixel defining film 190. That is, the opening 1905 of the pixel defining film 190 defines a light emitting area.

The capping layer 500 may be on the OLED 70. The capping layer 500 may serve to assist in effectively emitting light generated in the organic emission layer 720 while protecting the OLED 70 from external influences. The capping layer 500 may include a multiple-layered film, e.g., at least two layers having different refractive indexes. Accordingly, the capping layer 500 improves light efficiency by increasing an extraction ratio of light emitted from the organic emission layer 720 of the OLED 70.

Specifically, the capping layer 500 may include at least one high refractive film 510 and at least one low refractive film 520, i.e., the film 520 has a lower refractive index than the film 510, that are alternately stacked. FIG. 2 illustrates one high refractive film 510 and one low refractive film 520, but the first exemplary embodiment is not limited thereto.

Further, the high refractive film 510 is disposed at a top layer that is furthest separated from the OLED 70. That is, the top layer of the capping layer 500 is formed with the high refractive film 510.

The high refractive film 510 may have a refractive index within a range that is greater than or equal to 1.7 and less than 2.7. Further, the high refractive film 510 is made of at least one of an inorganic material and an organic material. That is, the high refractive film 510 may be formed with an inorganic film, an organic film, or an organic film containing inorganic particles.

An inorganic material that can be used for the high refractive film 510 may be, for example, zinc oxide, titanium oxide, zirconium oxide, silicon oxide, niobium oxide, tantalum oxide, tin oxide, nickel oxide, indium nitride, and gallium nitride.

An organic material that can be used for the high refractive film 510 may be, e.g., a polymer. A general organic material that can be used as the capping layer 500 may be, for example, acrylic, polyimide, and polyamide. An organic material that can be used for the high refractive film 510 includes poly(3,4-ethylenedioxythiophene, PEDOT, 4,4′-bis[N-(3-metylphenyl-N-phenyl amino] biphenyl (TPD, 4,4′,4″-tris[(3-metylphenyl)phenyl amino] triphenylamine (m-MTDATA) 1,3,5-tris [N,N-bis(2-metylphenyl-amino]-benzene(o-MTDAB)1,3,5-tris[N,N-bis(3-metylphenyl-amino]-benzene(m-MTDAB)1,3,5-tris[N,N-bis(4-metylphenyl)-amino]-benzene(p-MTDAB),4,4′-bis[N,N-bis(3-metylphenyl)-amino]-diphenylmethane(BPPM),4,4′-dicarbazolyl-1,1′-biphenyl(CBP), 4,4′,4″-tris(N-carbazol)triphenylamine(TCTA),2,2′,2″-(1,3,5-benzentolyl)tris-1-[phenyl-1H-benzoimidazol](TPBI), and 3-(4-biphenyl)-4-phenyl-5-t-butylphenyl-1,2,4-triazole (TAZ).

The low refractive film 520 may have a refractive index within a range of greater than 1.3 and less than 1.7. Further, the low refractive film 520 may be made of at least one of an inorganic material and an organic material. That is, the low refractive film 520 may be formed with an inorganic film, an organic film, or an organic film containing inorganic particles.

An inorganic material that can be used for the low refractive film 520 may be, for example, silicon oxide and magnesium fluoride. An organic material that can be used for the low refractive film 520 may be a polymer. An organic material that may be used for the low refractive film 520 may be, for example, acrylic, polyimide, polyamide, or Alq3 (Tris(8-hydroxyquinolinato)) aluminum.

Further, in the first exemplary embodiment, materials that can be used for the high refractive film 510 and the low refractive material film 520 are not limited to the above-described materials. Therefore, the high refractive film 510 and the low refractive film 520 may be made of various materials that are known to a person of ordinary skill in the art.

The low refractive film 520 may have a thickness t2 within a range of about 20 to 30 nm, and the high refractive film 510 may have a thickness t1 within a range of about 110 to 120 nm. When thicknesses of the low refractive film 520 and the high refractive film 510 are in the above-described ranges, light efficiency of light emitted from the organic emission layer 720 and that passes through the capping layer 500 may increase by more than 90%. However, the first exemplary embodiment is not limited to the above-described description. Therefore, a thickness of the low refractive film 520 and the high refractive film 510 can be appropriately adjusted, as needed.

The encapsulation substrate 210 is a transparent insulation substrate, e.g., glass, quartz, ceramic, or plastic substrate. The encapsulation substrate 210 may adhere to and seal the substrate main body 111 to cover the OLED 70. In this case, the encapsulation substrate 210 and the OLED 70 are separated from each other. A space between the encapsulation substrate 210 and the substrate main body 111 is sealed through a sealant in a periphery thereof (not shown).

Further, a gas 300, e.g., air, may be disposed in the separation space of the encapsulation substrate 210 and the OLED 70. The gas 300 may have a refractive index lower than a high refractive film. For example, when the gas 300 is air, the refractive index is about 1. By such a configuration, the OLED display 101 according to the first exemplary embodiment can improve light efficiency through the capping layer 500.

Due to a refractive index difference between the high refractive film 510 and the low refractive film 520 of the capping layer 500, a portion of light emitted from the organic emission layer 720 transmits through the capping layer 500 and another portion of the emitted light is reflected by the capping layer 500. Specifically, light is reflected at an interface of the high refractive film 510 and the low refractive film 520 and at an interface of the high refractive film 510 and the gas 300.

Light that is reflected by the capping layer 500 is reflected again at the first electrode 710 or the second electrode 730 and is amplified while repeating reflection. Further, light may be amplified while repeating reflection within the capping layer 500. That is, reflection may be repeated between an interface of the high refractive film 510 and the low refractive film 520 and an interface of the high refractive film 510 and the gas 300, thereby recovering light that would otherwise be lost due to reflection at the viewing surface back towards the OLED 70. The OLED display 101 effectively amplifies light through such a resonance effect, thereby improving light efficiency, i.e., the light extraction ratio.

Further, because light is reflected at an interface of the high refractive film 510 and the low refractive film 520 by a refractive index difference of the high refractive film 510 and the low refractive film 520, it is preferable that the high refractive film 510 and the low refractive film 520 have an appropriate refractive index difference, e.g., set such that a desired proportion of light is reflected at the interface. Further, the gas 300 contacting the high refractive film 510 may be regarded as a low refractive material.

Therefore, each of the high refractive film 510 and the low refractive film 520 has a refractive index of a determined range in consideration of a refractive index of the gas 300 and characteristics of a material that is used for manufacturing each of the refractive films 510 and 520. That is, the high refractive film 510 may have a refractive index greater than or equal to 1.7 and less than 2.7 according to a component that is used as a material of the high refractive film 510. The low refractive film 520 has a refractive index greater than 1.3 and less than 1.7 according to a component that is used as a material of the low refractive film 520. In this case, even if the same material is used, the high refractive film 510 and the low refractive film 520 may have different refractive indexes according to a manufacturing method.

Hereinafter, a structure of the driving circuit DC and the OLED 70 will be described in detail.

In FIGS. 1 and 2, the active matrix (AM) OLED display 101 of a 2Tr-1Cap structure having two thin film transistors (TFT) 10 and 20 and one capacitor 80 in one pixel is described, but the first exemplary embodiment is not limited thereto. Therefore, the OLED display 101 can have three or more TFTs and two or more capacitors in one pixel, and may have various structures as separate wiring is further formed. Here, a pixel is a minimum unit that displays an image, and the OLED display 101 displays an image through a plurality of pixels.

A switching TFT 10, a driving TFT 20, a capacitor 80, and the OLED 70 are each formed in each pixel. Here, a configuration including the switching TFT 10, the driving TFT 20, and the capacitor 80 is referred to as a driving circuit DC. In the pixel, a gate line 151 that is disposed in one direction, and a data line 171 and a common power source line 172 that are insulated from and intersect the gate line 151 are also formed. A pixel is defined by the gate line 151, the data line 171, and the common power source line 172 as the boundary, but a pixel is not limited thereto.

The OLED 70 includes the first electrode 710, the organic emission layer 720 on the first electrode 710, and the second electrode 730 on the organic emission layer 720. Holes and electrons from the first electrode 710 and the second electrode 730, respectively, are injected into the organic emission layer 720. When excitons formed by coupling of the injected holes and electrons drop from an exited state to a ground state, light is emitted.

The capacitor 80 may include a pair of capacitor plates 158 and 178 with an interlayer insulating layer 160 interposed therebetween. Here, the interlayer insulating layer 160 is a dielectric material. A capacitor capacity is determined by charges that are stored in the capacitor 80 and a voltage between both capacitor plates 158 and 178.

The switching TFT 10 may include a switching semiconductor layer 131, a switching gate electrode 152, a switching source electrode 173, and a switching drain electrode 174. The driving TFT 20 may include a driving semiconductor layer 132, a driving gate electrode 155, a driving source electrode 176, and a driving drain electrode 177.

The switching TFT 10 may serve as a switch that selects a pixel to emit light. The switching gate electrode 152 is connected to the gate line 151. The switching source electrode 173 is connected to the data line 171. The switching drain electrode 174 is separated from the switching source electrode 173 and is connected to one capacitor plate 158.

The driving TFT 20 applies a driving power source for allowing light emitting of the organic emission layer 720 of the OLED 70 within the selected pixel to the first electrode 710. The driving gate electrode 155 is connected to a capacitor plate 158 that is connected to the switching drain electrode 174. The driving source electrode 176 and the other capacitor plate 178 are each connected to the common power source line 172. The driving drain electrode 177 is connected to the first electrode 710 of the OLED 70 through a contact hole.

By such a structure, the switching TFT 10 operates by a gate voltage that is applied to the gate line 151 and thus performs a function of transferring a data voltage that is applied to the data line 171 to the driving TFT 20. A voltage corresponding to a difference between a common voltage that is applied from the common power source line 172 to the driving TFT 20 and a data voltage that is transferred from the switching TFT 10 is stored in the capacitor 80, and a current corresponding to the voltage that is stored in the capacitor 80 flows to the OLED 70 through the driving TFT 20, whereby the OLED 70 emits light.

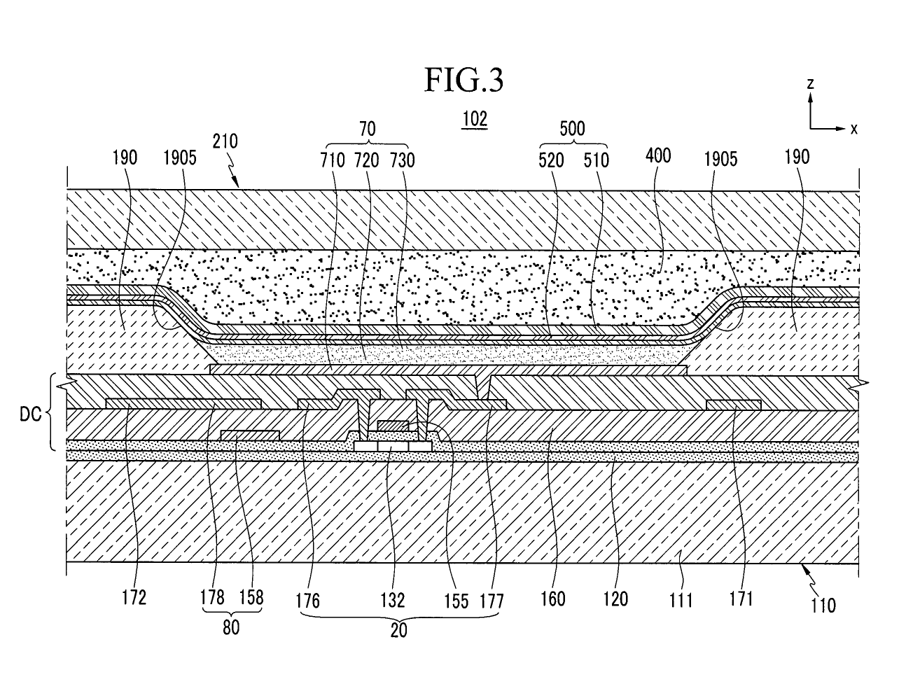

Hereinafter, a second exemplary embodiment will be described with reference to FIG. 3. As shown in FIG. 3, an OLED display 102 according to the second exemplary embodiment includes a non-gaseous filler 400 in the separation space between the OLED 70 and the encapsulation substrate 210. The non-gaseous filler 400 fills the inner space of the OLED display 102 instead of the gas 300.

The non-gaseous filler 400 may be made of an organic material, e.g., polymer having a refractive index of 1.7 or less. That is, the non-gaseous filler 400 may have a refractive index that is lower than a high refractive film 510 of a capping layer 500. By such a configuration, the OLED display 102 according to the second exemplary embodiment can improve light efficiency through the capping layer 500. Further, because the non-gaseous filler 400 fills the space within the OLED display 102 with a non-gaseous material, mechanical strength and durability of the OLED display 102 can be improved.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting diode (OLED) display, comprising:
a substrate main body;
an OLED on the substrate main body; and
a capping layer on the OLED, wherein the capping layer includes a film having at least two layers with different refractive indexes.

2. The OLED display as claimed in claim 1, wherein the film is an alternating stack of at least one high refractive film and at least one low refractive film.

3. The OLED display as claimed in claim 2, wherein the high refractive film is at a top layer of the capping layer furthest from the OLED.

4. The OLED display as claimed in claim 3, wherein the high refractive film has a refractive index within a range that is greater than or equal to 1.7 and less than 2.7.

5. The OLED display as claimed in claim 4, wherein the high refractive film is made of at least one of an inorganic material and an organic material.

6. The OLED display as claimed in claim 5, wherein the inorganic material comprises at least one of zinc oxide, titanium oxide, zirconium oxide, silicon oxide, niobium oxide, tantalum oxide, tin oxide, nickel oxide, indium nitride, and gallium nitride.

7. The OLED display as claimed in claim 5, wherein the organic material is a polymer.

8. The OLED display as claimed in claim 3, wherein the low refractive film has a refractive index of a range that is greater than 1.3 and less than 1.7.

9. The OLED display as claimed in claim 8, wherein the low refractive film includes at least one of an inorganic material and an organic material.

10. The OLED display as claimed in claim 9, wherein the inorganic material comprises at least one of silicon oxide and magnesium fluoride.

11. The OLED display as claimed in claim 9, wherein the organic material is a polymer.

12. The OLED display as claimed in claim 3, further comprising an encapsulation substrate that adheres to and seals the substrate main body to cover the OLED, the encapsulation substrate and the OLED having a separation space between them.

13. The OLED display as claimed in claim 12, further comprising a gas in the separation space between the encapsulation substrate and the OLED.

14. The OLED display as claimed in claim 13, wherein the gas has a refractive index lower than that of the high refractive film.

15. The OLED display as claimed in claim 12, further comprising a non-gaseous filler in the separation space between the encapsulation substrate and the OLED.

16. The OLED display as claimed in claim 15, wherein the non-gaseous filler has a refractive index lower than that of the high refractive film.

17. The OLED display as claimed in claim 16, wherein the non-gaseous filler is made of an organic material.

18. The OLED display as claimed in claim 17, wherein the organic material is a polymer.

19. The OLED display as claimed in claim 1, wherein the OLED comprises:
a first electrode;
an organic emission layer on the first electrode; and
a second electrode on the organic light emitting layer and that is disposed relatively most adjacent to the capping layer, wherein the second electrode is made of one of a transparent material and a transflective material.

20. The OLED display as claimed in claim 18, wherein the first electrode is formed with a reflective layer.
